(19) United States
(12) Patent Application Publication
(10) Pub. No.: US 2022/0320900 A1
(43) Pub. Date: Oct. 6, 2022

(54) SENSING SYSTEM AND ASSOCIATED COMPONENTS AND METHODS

(71) Applicant: Baker Hughes Oilfield Operations LLC, Houston, TX (US)

(72) Inventors: Navin Sakthivel, Spring, TX (US); Aaron Avagliano, Tomball, TX (US); Ashwin Chandran, Spring, TX (US); Lakshmi Jyotshna Vendra, Spring, TX (US)

(21) Appl. No.: 17/658,024

(22) Filed: Apr. 5, 2022

Related U.S. Application Data
(60) Provisional application No. 63/170,992, filed on Apr. 5, 2021.

(51) Int. Cl. H02J 50/00; H02J 7/35; H02J 7/00

(52) U.S. Cl. CPC H02J 50/001; H02J 7/35; H02J 7/0068

(57) ABSTRACT

A self-powered sensing system. The sensing system may include a power generator at least partially disposed in a diamond composite heat sink configured to harvest energy from a hazardous environment. The sensing system may further include an energy storage device operatively coupled to the power generator. The sensing system may also include at least one sensor operatively coupled to the energy storage device and a sensor antenna operatively coupled to the at least one sensor. The sensor antenna may be configured to transmit information collected from the at least one sensor to an operation system. The at least one sensor may include a resonance tube having a three-dimensional lattice structure.

### PRIORITY CLAIM

This application claims the benefit of the filing date of U.S. Provisional Patent Application Ser. No. 63/170,992, filed Apr. 5, 2021, for “METHODS OF MANUFACTURING ELECTRONIC COMPONENT, SENSORS, AND ASSOCIATED SYSTEMS,” the disclosure of which is hereby incorporated herein in its entirety by this reference.

### TECHNICAL FIELD

Embodiments of the present disclosure generally relate to sensing systems and methods of manufacturing components of the sensing systems. In particular, embodiments of the present disclosure relate to self-powered sensing systems designed for use in hazardous environments and methods of manufacturing components of the same.

### BACKGROUND

Sensors are a part of most industrial operations. Sensors provide information about the respective operation to an operator or operation system, which then can make operational decisions, such as control adjustments, stopping processes, replacing components, etc. The sensors communicate the information to the operators or operation system through a communication system. Communication systems may include wired communication using direct wired connections or network communication networks or wireless communication, such as using radio waves to transmit information between a transmitter and a receiver.

### SUMMARY

Embodiments of the disclosure may include a self-powered sensing system configured for use in a harsh environment. The sensor system may include a power generator at least partially disposed in a diamond composite heat sink. The power generator may be configured to harvest energy from the hazardous environment. The sensor system may further include an energy storage device operatively coupled to the power generator. The energy storage device may be configured to store energy generated by the power generator. The sensor system may also include at least one sensor operatively coupled to the energy storage device. The sensor system may further include a sensor antenna operatively coupled to the energy storage device and the at least one sensor. The sensor antenna may be configured to transmit information collected from the at least one sensor to an operation system.

Another embodiment of the disclosure may include a resonance sensor. The resonance sensor may include a signal supply, a supply piezoelectric transducer, a receiver piezoelectric transducer, and a resonance tube extending between the supply piezoelectric transducer and the receiver piezoelectric transducer. The resonance tube may include a three-dimensional lattice structure.

Another embodiment of the disclosure may include a method of forming an antenna. The method may include forming a dielectric base material through an additive manufacturing process, the dielectric base material comprising a ceramic material. The method may further include forming a conductive material over the dielectric base material through a second additive manufacturing process. The method may also include brazing the conductive material to the dielectric base material

### BRIEF DESCRIPTION OF THE DRAWINGS

While the specification concludes with claims particularly pointing out and distinctly claiming embodiments of the present disclosure, the advantages of embodiments of the disclosure may be more readily ascertained from the following description of embodiments of the disclosure when read in conjunction with the accompanying drawings in which:

FIG. 1 illustrates a communication system in accordance with an embodiment of the disclosure;

FIGS. 2A and 2B illustrate different views of a power supply device in accordance with an embodiment of the disclosure;

FIG. 3A illustrates an energy storage device in accordance with an embodiment of the disclosure;

FIG. 3B illustrates an enlarged view of a portion of the energy storage device of FIG. 3A;

FIGS. 4A and 4B illustrate an antenna in accordance with an embodiment of the disclosure;

FIG. 5A illustrates an acoustic resonance sensor in accordance with an embodiment of the disclosure;

FIG. 5B illustrates an enlarged view of a portion of the acoustic resonance sensor of FIG. 5A; and

FIG. 6 illustrates a microwave resonance sensor in accordance with an embodiment of the disclosure.

### DETAILED DESCRIPTION

The illustrations presented herein are not meant to be actual views of any particular electronic component or method associated therewith or component thereof, but are merely idealized representations employed to describe illustrative embodiments. The drawings are not necessarily to scale.

As used herein, the term “substantially” in reference to a given parameter means and includes to a degree that one skilled in the art would understand that the given parameter, property, or condition is met with a small degree of variance, such as within acceptable manufacturing tolerances. For example, a parameter that is substantially met may be at least about 90% met, at least about 95% met, at least about 99% met, or even at least about 100% met.

As used herein, relational terms, such as “first,” “second,” “top,” “bottom,” etc., are generally used for clarity and convenience in understanding the disclosure and accompanying drawings and do not connote or depend on any specific preference, orientation, or order, except where the context clearly indicates otherwise.

As used herein, the term “and/or” means and includes any and all combinations of one or more of the associated listed items.

As used herein, the terms “vertical” and “lateral” refer to the orientations as depicted in the figures.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise. For example, these terms may refer to an orientation of elements of any electronic component when utilized in a conventional manner.

As used herein, the term “about” used in reference to a given parameter is inclusive of the stated value and has the meaning dictated by the context (e.g., it includes the degree of error associated with measurement of the given parameter, as well as variations resulting from manufacturing tolerances, etc.).

Sensing systems, such as for condition monitoring that facilitate operational safety, preventive maintenance and diagnostics in chemical processing, manufacturing, energy production industries may be located in harsh environments. An additive manufacturing process may be used for manufacturing components of an energy harvesting wireless sensing system for use in harsh process environments. Harsh environments may include environments having extreme temperatures, pressures, fluid flows, and/or accessibility challenges that may impair the deployment of sensing systems to monitor any stochastic abnormal signal from the process units for preventing the outages, accidents and revenue loss in such applications.

Extreme conditions may be problematic for conventional communication systems. For example, the extreme conditions may destroy traditional wiring, such as by melting insulation or corroding contacts and insulation. Furthermore, the extreme conditions may inhibit wireless communication, such as by melting, corroding, or delaminating materials of antennas of the transmitters or receivers. Embodiments of the disclosure may result in a communication system configured to operate in extreme conditions. For example, communication systems of the disclosure may substantially limit external wiring, such as through self-powered systems and/or internal power storage systems. Embodiments of the disclosure may also include antennas formed from components and through processes that are configured to withstand the extreme conditions.

Vulnerable components of a process or equipment may be condition monitored using the system described below. Embodiments of the present disclosure may develop and enable 3D printing designs, processes and materials that enable printing integrated self-powered sensing systems that may conform to the surface of plant equipment and may facilitate compact spacing in harsh environments involving temperatures of at least about 200° C., pressures of at least about 20 kpsi, and/or the presence of process fluids, corrosive elements, fatigue and creep conditions, etc. This may include applications in combined cycle turbine, thermal power plant systems, fuel cells, carbon capture systems, refineries, chemical processing fractional columns and distillation columns, nuclear power plant components, effluent processing filter systems, fuel and energy storage units, geothermal systems etc.

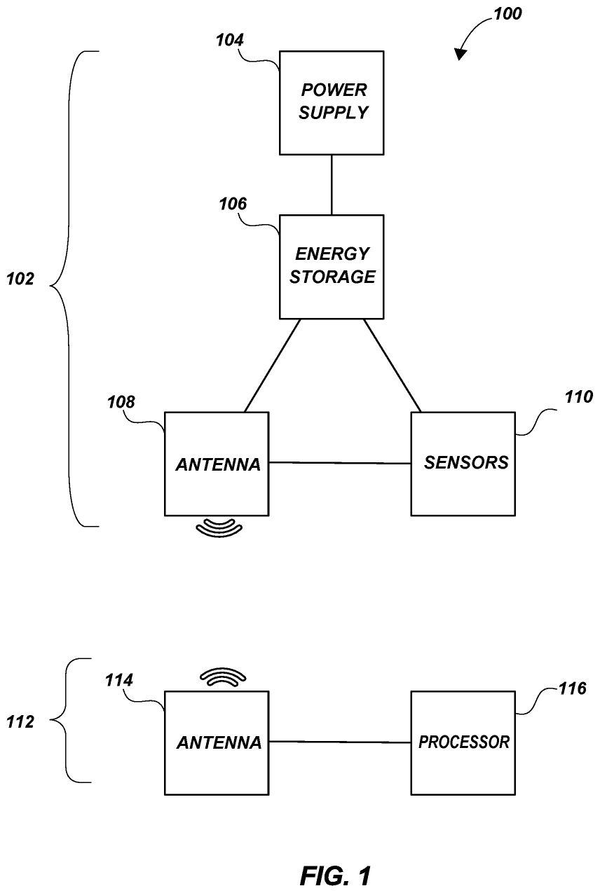

FIG. 1 illustrates a schematic view of a communication system 100 including a self-powered sensing system 102. The self-powered sensing system 102 may include a power supply 104, an energy storage device 106, sensors 110, and an antenna 108. The power supply 104 may include a power generation device, such as solar cells or thermo-electric generators (TEGs). In other embodiments, the sensing system 102 may receive power from an outside source, such as a connection to supply power from another component of the associated system, such as line-voltage from a power outlet, a DC power source from a control circuit, etc.

The self-powered sensing system 102 may also include an energy storage device 106, such as a battery or capacitor. The energy storage device 106 may be configured to provide an even supply of power to the associated components of the self-powered sensing system 102. For example, the energy storage device 106 may supply power to the component when the power supply 104 is not supplying power (e.g., not generating power) or when the power being supplied or generated by the power supply 104 is less than the power demand from the components. The energy storage device 106 may also collect and store surplus power, such as when the power supply 104 is providing or generating more energy than is being used by the components.

The components may include among other things sensors 110 and an antenna 108. The sensors 110 may be configured to measure conditions, elements, features, etc., in the environment surrounding the sensor or to detect the occurrence of an event, the presence of an element or component, the removal of an element or component, etc. The sensors 110 may receive power through the energy storage device 106. Sensors may include strain sensors (e.g., strain gauges), pressure sensors, eddy current sensors, Hall-effect sensors, acoustic transducers, acoustic resonance spectroscopy sensors, microwave resonance spectroscopy sensors, etc.

The self-powered sensing system 102 may be configured to communicate with an operation system 112 wirelessly. For example, the self-powered sensing system 102 may include an antenna 108, which may be coupled to one or more of a transmitter or a receiver. A transmitter may provide information from the sensors 110 to be transmitted by the antenna 108 to the operation system 112. The antenna 108 may also receive information, such as instructions, from the operation system 112. The antenna 108 may then provide the information to the receiver, which may interpret the information or pass the information to a separate processor to be interpreted.

The operation system 112 may also include an antenna 114. The antenna 114 may similarly receive and/or transmit information from/to the self-powered sensor system. The operation system 112 may include a processor 116, which may be operably coupled to the antenna 114, such as through a transmitter and/or receiver. The processor may process the information received from the self-powered sensor system 102 through the antenna 114. For example, the processor may evaluate the information received from the self-powered sensor system and adjust operational parameters based on the information. In some cases, the processor may interpret the signal received from the self-powered sensor system and display the values to a user interface, such as a graphical user interface (GUI), touch screen, computer display, tablet, etc. In other cases, the processor may transmit the information received from the self-powered sensor system 102 to another processor of another component of the operation system 112.

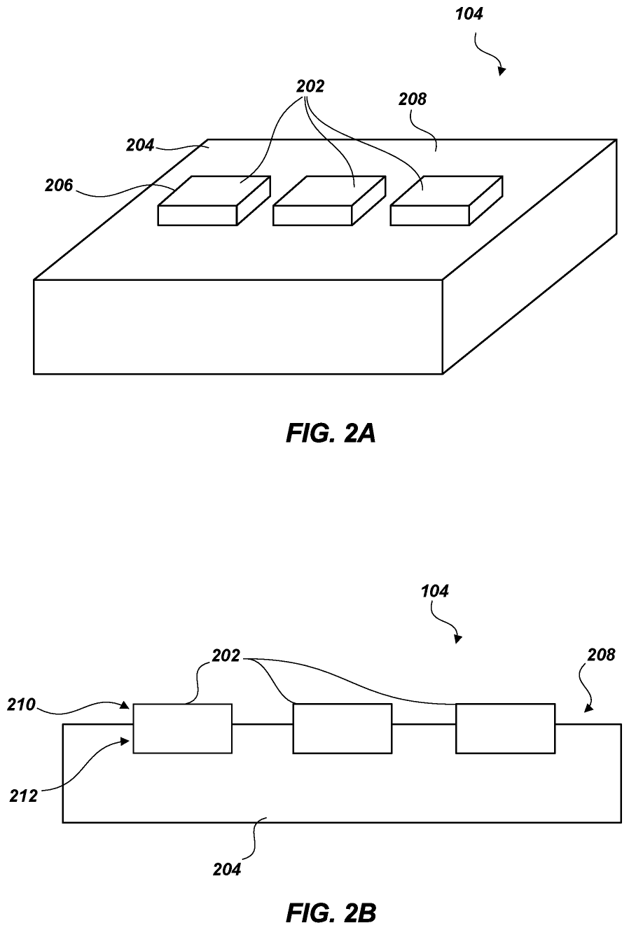

FIGS. 2A and 2B illustrate a power supply 104 of a self-powered sensor system deployed in an extreme environment. The power supply 200 may include one or more energy harvesting devices 202, such as solar cells or thermo-electric generators (TEGs). A TEG may be formed from a thermo-electric material, such as lanthanum telluride (La₃₋ₓ Te₄), which is configured to generate electrical power based on a temperature difference across the thermo-electric material. Increasing the temperature differential across the TEG may increase the efficiency of the TEG. Solar cells, such as perovskite solar cells, convert light energy to electrical power. The efficiency of solar cells may decrease as the temperature of the solar cells increase.

The employment of energy harvesting devices 202, such as solar cells (e.g., perovskite solar cells), or TEGs for energy harvesting in a high temperature environments may be challenging due to the inefficiencies introduced at higher temperatures. The efficiency of the energy harvesting devices 202 may be increased in high temperature environments by disposing the energy harvesting devices 202 in a heat sink 204. The heat sink 204 may be formed to include one or more cavities 206 in a surface 208 of the heat sink 204. The energy harvesting devices 202 may be disposed in the one or more cavities 206, such that the heat sink 204 may absorb heat from the energy harvesting devices 202 increasing the efficiency of the energy harvesting devices 202 in a high temperature environment.

The heat sink 204 may be formed from a diamond composite material having a high heat transfer coefficient. The heat sink 204 may be formed through an additive manufacturing process (e.g., 3-D printing). The additive manufacturing process may facilitate conforming the shape of the heat sink 204 to match a mounting component and/or to position the cavities 206 for the energy harvesting devices 202 in an optimal position to further increase the efficiency of the energy harvesting devices 202. In some embodiments, the heat sink 204 may be coupled to a larger common heat sink. In other embodiments, the heat sink 204 may include features configured to reject heat to the surrounding atmosphere, such as fins, ribs, etc. In some embodiments, the heat sink 204 may be coupled between two different environments, such that the heat sink 204 may transfer heat from the energy harvesting devices 202 in the high temperature environment to an environment having a lower temperature than the environment around the energy harvesting devices 202.

The energy harvesting devices 202 may be at least partially enclosed in a matrix of heat sink 204. Additive manufacturing may facilitate a design of the cavities 206 that encloses a buried portion 212 of the energy harvesting devices 202 submerged into the matrix of the heat sink 204. In some embodiments, an exposed portion 210 may remain outside the matrix of the heat sink 204. Thus, the exposed portion 210 may be exposed to the ambient temperature. In a high temperature environment, the exposed portion 210 of the energy harvesting device 202 may coincide with the high temperature side of a TEG, such that the buried portion 212 may coincide with the low temperature side of the TEG. Thus, a temperature difference between the ambient temperature and an internal temperature of the heat sink 204 may define the temperature differential across the TEG. The complex geometries achievable through additive manufacturing processes may facilitate TEG designs with higher efficiency than conventional TEGs. For example, TEGs coupled to a heat sink 204 formed from a diamond composite may provide a high temperature gradient where the ambient temperature is a high temperature. In other embodiments, such as where the energy harvesting device 202 is a solar cell, the exposed portion 210 may be substantially reduced, such that only an upper surface of the energy harvesting device 202 is not submerged in the heat sink 204.

As described above, the power supply 104 may be coupled to a power storage device 106. Electrochemical device technology, such as that used for energy storage (e.g., batteries, capacitors, etc.), may generally be limited to room temperature, because the internal components such as the electrodes, electrolytes, electrode electrolyte interfaces may not be stable at elevated temperatures and the charge/discharge cycling within the device may cause additional thermal fluctuations during the operations. Electrodes or electrolytes are also sensitive to moisture and oxygen in the atmosphere and may have certain protocols to be followed during the electrode preparation and assembly to maintain active material loading, avoid shortening of the electrodes and low impedance to avoid resistive and heat related energy losses.

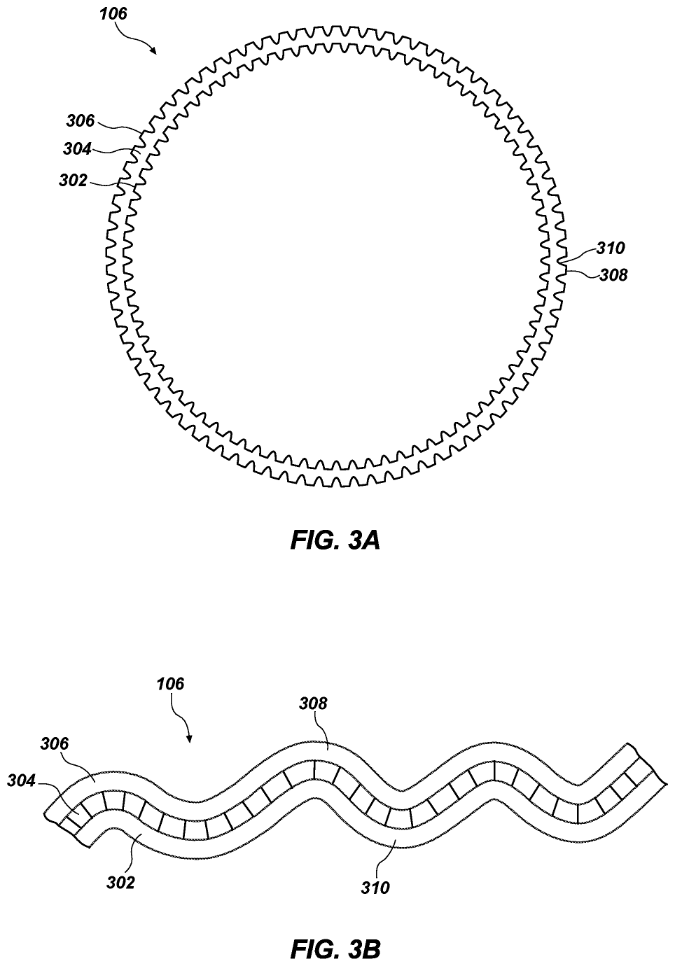

Employing a solid electrolyte (e.g., ceramic or solid polymer) may circumvent several of the mentioned vulnerabilities. FIGS. 3A and 3B illustrate an energy storage device 106. The energy storage device 106 may include a first electrode 302 and a second electrode 306 separated by a dielectric material 304. The energy storage capacity of the energy storage device 106 may correlate to a surface area of the first electrode 302 and the second electrode 306. The energy storage device 106 may be formed through an additive manufacturing process that may facilitate fabrication of devices with complex architectures and potentially higher energy and power densities. For example, as illustrated in FIGS. 3A and 3B, the first electrode 302 and the second electrode 306 may be formed with a corrugated surface to increase the total surface area in a given volume (e.g., increasing a surface area to volume ratio). The corrugated surface may be characterized by a pattern of peaks 308 and valleys 310. The additive manufacturing process may facilitate forming an energy storage device 106 that conforms to the surface of a structure, such as a cylindrical structure as illustrated in FIG. 3A and other more intricate surfaces. By controlling the loading of the active materials while simultaneously printing other form factors, the device may be specifically tailored for applications of batteries and supercapacitors on conformable surfaces, tool bodies, smart clothing, flexible electronics, etc.

FIG. 3B illustrates an enlarged view of a portion of the energy storage device 106. The first electrode 302 may be formed of a conductive material configured to withstand harsh environmental conditions, such as nickel-chromium alloys (e.g., INCONEL® 718), gold, silver, titanium, etc. The first electrode 302 may be formed through an additive manufacturing process.

The dielectric material 304 may be formed from a high temperature dielectric material, such as ceramic materials (e.g., aluminum oxides, zirconium oxides, etc.) or high temperature polymer materials (e.g., polyether ether ketone (PEEK), polybenzimidazole (PBI), polyimide (PI), etc.). The dielectric material 304 may be formed through an additive manufacturing process over the first electrode 302. The dielectric material 304 may substantially conform to the shape of the first electrode 302, such that the dielectric material 304 may follow a corrugated pattern with a pattern of peaks 308 and valleys 310 substantially similar to the first electrode 302.

The second electrode 306 may be formed from another conductive material, such as nickel-chromium alloys (e.g., INCONEL® 718), gold, silver, titanium, etc. In some embodiments, the material of the second electrode 306 may be the same material as that used to form the first electrode 302. In other embodiments, the second electrode 306 may be formed from a different conductive material than the first electrode 302. The second electrode 306 may be formed through another additive manufacturing process over the dielectric material 304. The second electrode 306 may substantially conform to the shape of an adjoining surface of the dielectric material 304, such that the second electrode 306 may follow a corrugated pattern similar to the first electrode 302 including a pattern of peaks 308 and valleys 310.

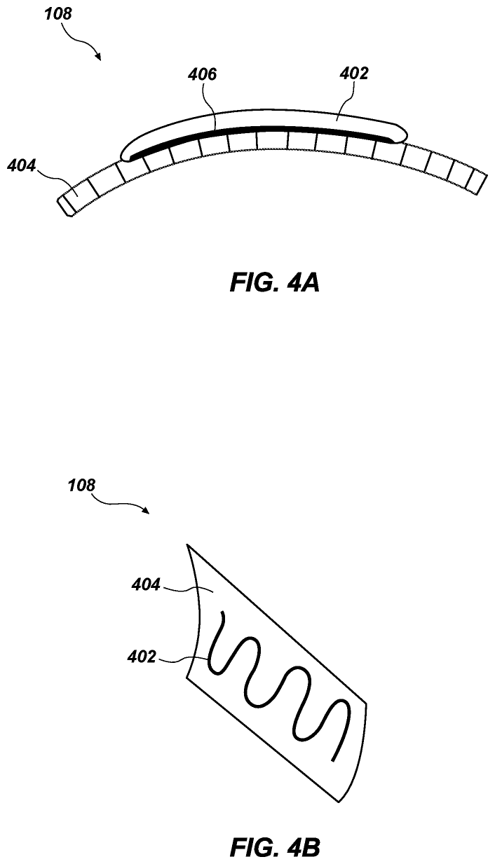

FIGS. 4A and 4B illustrate an embodiment of an antenna 108. An antenna includes a conductive material 402 coupled to a dielectric material 404. Conventional wireless antennas may have limited operating temperatures and/or may involve high cost and lead times. Most of the conventional antennas employ polymer materials for the dielectric material 404 and copper for the conductive material 402. Conventional polymer materials may not be configured to withstand harsh conditions, such as high temperatures. Similarly, as the temperature rises the conductivity of copper may decrease.

An antenna 108 for use in harsh conditions may be formed with a dielectric material 404 that is configured to withstand high temperatures, such as a ceramic dielectric (e.g., aluminum oxides, zirconium oxides, etc.) and a conductive material 402 that is configured to maintain relatively high conductivity at high temperatures, such as nickel-chromium alloys (e.g., INCONEL® 718), gold, silver, titanium, etc.

High temperatures may cause delamination of two materials having significantly different coefficients of thermal expansion, such as metals and ceramics. The conductive material 402 may be coupled to the dielectric material 404 through a temperature resistant coupling process, such as brazing. Brazing the conductive material 402 to the dielectric material 404 may substantially prevent the conductive material 402 from delaminating from the dielectric material 404 at high temperatures.

Forming the antenna 108 through an additive manufacturing process may substantially reduce the lead time of the antenna 108 and facilitate greater amounts of customization. For example, additive manufacturing processes may allow antennas to be formed to conform to a surface of the associated part. This may facilitate mounting the antenna 108 in unobtrusive locations, which may substantially reduce the likelihood of the antenna 108 becoming damaged and/or may facilitate positioning the antenna 108 in confined areas. Conforming the antenna to a surface of the associated part may also facilitate more robust antenna designs and/or greater ranges.

As illustrated in FIG. 4B, the conductive material 402 of the antenna 106 may be arranged in a non-linear pattern, which may increase a length of the conductive material 402 of the antenna 106 without significantly increasing the area of the associated part that is covered by the antenna 106. Increasing a length of the conductive material 402 of the antenna 106 may increase a range of the antenna 106 and/or a strength of the signal from the antenna 106. Increasing the range of the antenna 106 may facilitate positioning the operation system communication components a greater distance from the antenna 106, which may reduce the complexity of system, such as by reducing the number of communication locations, repeaters, etc., needed to communication with the different self-powered sensor systems 102.

As described above, the self-powered sensor system 102 may include multiple different types of sensors 110. Sensors may include strain sensors (e.g., strain gauges), pressure sensors, eddy current sensors, Hall-effect sensors, acoustic transducers, acoustic resonance spectroscopy sensors, microwave resonance spectroscopy sensors, etc.

Acoustic transducers may be employed to measure viscosity, density, crack detection in solids, stress levels etc. Additive manufactured impedance matching layers and backing layers in acoustic transducers may improve the sensitivity and signal strength of the acoustic transducers. Manufacturing acoustic transducers or components thereof through additive manufacturing may improve efficiency of the acoustic transducers for measurements in a harsh environment.

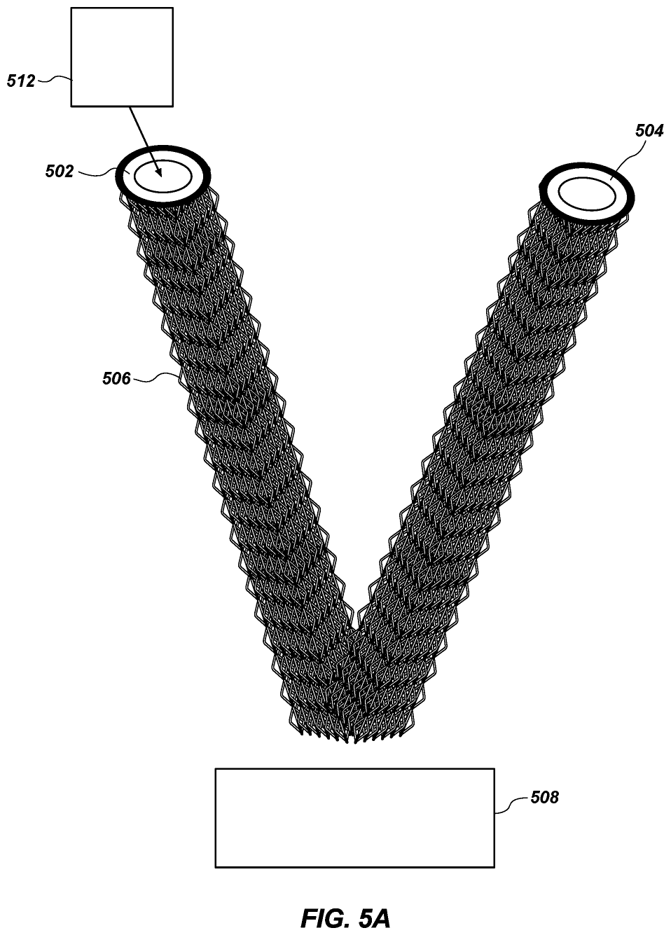

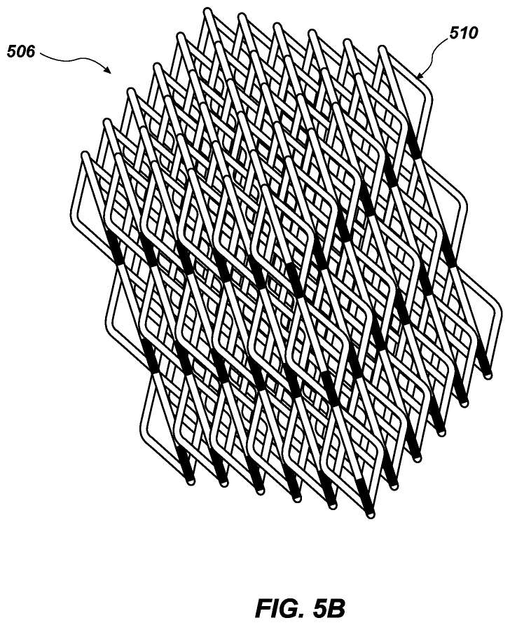

Acoustic Resonance Spectroscopy may be used to identify target chemicals, gas, or corrosion products. FIGS. 5A and 5B illustrate an embodiment of an acoustic resonance spectroscopy sensor 500. The acoustic resonance spectroscopy sensor 500 may include a supply piezoelectric transducer 502, a receiver piezoelectric transducer 504, and a resonance tube 506 extending between the supply piezoelectric transducer 502 and the receiver piezoelectric transducer 504. An acoustic wave generator 512 may provide a supply acoustic signal (e.g., sound wave), such as white noise, ultrasonic sound waves, etc., to the resonance tube 506 through the supply piezoelectric transducer 502. The supply piezoelectric transducer 502 may convert the supply acoustic signal to an electric signal. The acoustic signal may pass through the resonance tube 506 into a sample 508. In some embodiments, the sample 508 may be a solid material, such as rock. In other examples, the sample 508 may be a fluid, such as a liquid or gas, such that the resonance tube 506 may be submerged in the sample 508. A modified acoustic signal may continue through the resonance tube 506 to the receiver piezoelectric transducer 504. The receiver piezoelectric transducer 504 may then convert the modified acoustic signal to an electrical signal. The acoustic resonance spectroscopy sensor 500 may then evaluate a difference between the electrical signal from the supply piezoelectric transducer 502 and the receiver piezoelectric transducer 504 to determine properties of the sample 508.

FIG. 5B illustrates an enlarged view of the resonance tube 506 of the acoustic resonance spectroscopy sensor 500. The resonance tube 506 may be formed from a material having a low resistance to acoustic signals, such as silicon dioxide (quartz). The resonance tube 506 may be formed through an additive manufacturing process, which may facilitate the formation of complex geometry in the resonance tube 506. As illustrated, the resonance tube 506 may be formed from a three dimensional lattice structure 510. Forming the resonance tube 506 from a lattice structure 510 may increase the sensitivity and/or resolution of the acoustic resonance spectroscopy sensor 500.

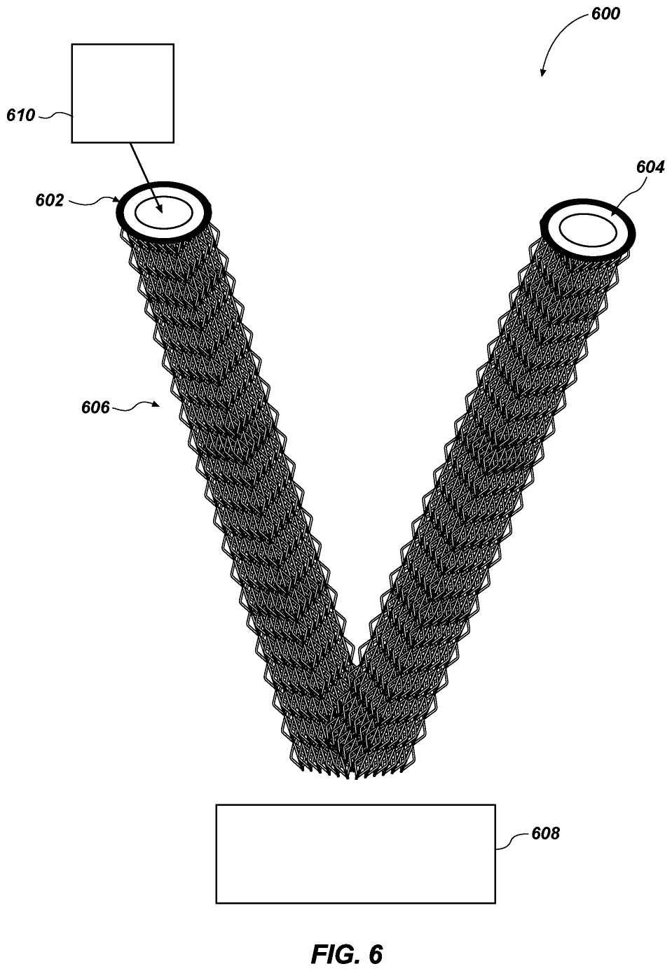

Microwave Resonance Spectroscopy may be used to identify target chemicals, gas, or corrosion products. FIG. 6 illustrates an embodiment of a microwave resonance spectroscopy sensor 600. The microwave resonance spectroscopy sensor 600 may include a supply piezoelectric transducer 602, a receiver piezoelectric transducer 604, and a resonance tube 606 extending between the supply piezoelectric transducer 602 and the receiver piezoelectric transducer 604. A microwave generator 610 may supply a microwave signal to the resonance tube 606 through the supply piezoelectric transducer 602. The supply piezoelectric transducer 602 may convert the supply microwave signal to an electric signal. The supply microwave signal may pass through the resonance tube 606 into a sample 608. As described above, the sample 608 may be a solid material, such as rock or a fluid, such as a liquid or gas. A modified microwave signal may continue through the resonance tube 606 to the receiver piezoelectric transducer 604. The receiver piezoelectric transducer 604 may then convert the modified microwave signal to an electrical signal. The microwave resonance spectroscopy sensor 600 may then evaluate a difference between the electrical signal from the supply piezoelectric transducer 602 and the receiver piezoelectric transducer 604 to determine properties of the sample 608.

The resonance tube 606 may be formed from a material having a low resistance to microwave signals, such as metal materials (e.g., aluminum, copper, gold, magnesium, silver, zinc, etc.). The resonance tube 606 may be formed through an additive manufacturing process, which may facilitate the formation of complex geometry in the resonance tube 606. The resonance tube 606 may be formed with similar geometry to that illustrated in FIG. 5B of the resonance tube 506 of the acoustic resonance sensor 500. For example, the resonance tube 606 may be formed from a three dimensional lattice structure. Forming the resonance tube 606 from a lattice structure may increase the sensitivity and/or resolution of the microwave resonance spectroscopy sensor 600.

In some embodiments, strain gauges may be formed directly on a target part's surface through an additive manufacturing process. The strain gauge may conform to a shape of the target part's surface, which may enable strain gauges to be deployed in complicated areas of operation and/or over areas having complex geometry. Furthermore, the strain gauges may remain fixed to the target part in harsh conditions that may break down the adhesive on conventional strain gauges.

Eddy current sensors may be formed through an additive manufacturing process by forming a soft magnetic material and conductive coil. An additive manufactured eddy current sensors may operate in high temperatures enabling the use of eddy current sensors for applications, such as measuring displacement, position, proximity of actuation or moving systems in process plants.

Different applications may have different operational requirements, such as operating temperature, vibration resistance, conductivity of the trace, dimensions and tolerances, adhesion to dielectric, dielectric break down potential, thermal stability, vibration and shock stability. For example, some the applications may include environments having extreme temperatures, pressures, fluid flows, and/or accessibility challenges.

The additive manufacturing process and post curing process parameters may be optimized to meet the above discussed operational requirements. This may facilitate the customization of the sensing system and components thereof for specific applications.

In some embodiments, a robotic arm may be used for the deposition process for mass customization of the sensing system components. The robotic arm may be used to control the positioning of the additive manufacturing process components, such as the nozzle. The robotic arm may enable both mass production of the sensing system components as well as customization without requiring new tooling for every customization.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A self-powered sensing system configured for use in a harsh environment, the self-powered sensing system comprising:
a power generator at least partially disposed in a diamond composite heat sink, the power generator configured to harvest energy from the hazardous environment;
an energy storage device operatively coupled to the power generator, the energy storage device configured to store energy generated by the power generator;
at least one sensor operatively coupled to the energy storage device; and
a sensor antenna operatively coupled to the energy storage device and the at least one sensor, the sensor antenna configured to transmit information collected from the at least one sensor to an operation system.

2. The self-powered sensing system of claim 1, wherein the power generator comprises a solar cell.

3. The self-powered sensing system of claim 1, wherein the power generator comprises a thermo-electric generator.

4. The self-powered sensing system of claim 3, the thermo-electric generator comprising:
a buried portion substantially submerged in the diamond composite heat sink; and
an exposed portion extending away from a surface of the diamond composite heat sink.

5. The self-powered sensing system of claim 1, wherein the energy storage device comprises:
a first electrode formed from a first conductive material;
a second electrode formed from a second conductive material; and
a dielectric layer formed from a ceramic material, the dielectric layer positioned between the first electrode and the second electrode.

6. The self-powered sensing system of claim 5, wherein the first electrode comprises a first corrugated surface including a pattern of peaks and valleys, and the second electrode comprises a second corrugated surface substantially matching the pattern of peaks and valleys of the first corrugated surface.

7. The self-powered sensing system of claim 1, wherein the at least one sensor is selected from among the group consisting of strain gauges, eddy current sensors, acoustic transducers, acoustic resonance spectroscopy sensors, or microwave resonance spectroscopy sensors.

8. The self-powered sensing system of claim 1, wherein the sensor antenna comprises a conductive material formed on a dielectric material, wherein the dielectric material comprises a ceramic material.

9. The self-powered sensing system of claim 8, wherein the conductive material is selected from the group consisting of nickel-chromium alloys, gold, silver, and titanium.

10. The self-powered sensing system of claim 8, wherein the conductive material is brazed to the dielectric material.

11. A resonance sensor, comprising:
a signal supply;
a supply piezoelectric transducer;
a receiver piezoelectric transducer;
a resonance tube extending between the supply piezoelectric transducer and the receiver piezoelectric transducer, the resonance tube including a three-dimensional lattice structure.

12. The resonance sensor of claim 11, wherein the signal supply comprises an acoustic wave generator.

13. The resonance sensor of claim 12, wherein the resonance tube comprises silicon dioxide forming the three-dimensional lattice structure.

14. The resonance sensor of claim 11, wherein the signal supply comprises a microwave generator.

15. The resonance sensor of claim 14, wherein the resonance tube comprises a metal material forming the three-dimensional lattice structure.

16. The resonance sensor of claim 11, wherein the three-dimensional lattice structure of the resonance tube is formed by an additive manufacturing process.

17. A method of forming an antenna, comprising:
forming a dielectric base material by an additive manufacturing process, the dielectric base material comprising a ceramic material;
forming a conductive material over the dielectric base material by a second additive manufacturing process; and
brazing the conductive material to the dielectric base material.

18. The method of claim 17, wherein forming the dielectric base material further comprises forming the dielectric base material over a surface of an associated component.

19. The method of claim 18, wherein forming the dielectric base material over the surface of the associated component further comprises conforming the dielectric base material to the surface of the associated component.

20. The method of claim 17, wherein forming the conductive material over the dielectric base material further comprises forming the conductive material in a non-linear pattern over a surface of the dielectric base material.
